(19) United States
(12) Patent Application Publication
(10) Pub. No.: US 2025/0066636 A1
(43) Pub. Date: Feb. 27, 2025

(54) RESIN COMPOSITION FOR FORMING PHASE-SEPARATED STRUCTURE AND METHOD FOR PRODUCING STRUCTURE HAVING PHASE-SEPARATED STRUCTURE

(71) Applicant: TOKYO OHKA KOGYO CO., LTD., Kawasaki-shi (JP)

(72) Inventors: Ken MIYAGI, Kawasaki-shi (JP); Takahiro DAZAI, Kawasaki-shi (JP); Shota IINO, Kawasaki-shi (JP)

(21) Appl. No.: 18/776,834

(22) Filed: Jul. 18, 2024

(30) Foreign Application Priority Data
Jul. 24, 2023 (JP) 2023-119926

(51) Int. Cl. C09D 153/00

(52) U.S. Cl. CPC C09D 153/00

(57) ABSTRACT

A resin composition for forming a phase-separated structure that can improve a process margin. A resin composition for forming a phase-separated structure containing a predetermined block copolymer A and a predetermined block copolymer B, the composition having a ratio (L0_{B}/L0_{A}) of L0 of the block copolymer B (L0_{B}) to L0 of the block copolymer A (L0_{A}) of 0.70 or more and 1.20 or less.

### PHASE-SEPARATED STRUCTURE

This application claims priority to Japanese Patent Application No. 2023-119926, filed Jul. 24, 2023, the entire content of which is incorporated herein by reference.

### BACKGROUND OF THE INVENTION

### Field of the Invention

The present invention relates to a resin composition for forming a phase-separated structure and a method for producing a structure having a phase-separated structure.

### Related Art

In recent years, following further miniaturization of a large-scale integrated circuit (LSI), a technique for processing a finer structure has been demanded.

For such a demand, a technique has been developed for forming a finer pattern utilizing a phase-separated structure formed by self-organization of a block copolymer in which blocks incompatible with each other are bonded (see, for example, Patent Document 1).

The above-mentioned block copolymer is separated (phase-separated) in a microregion due to repulsion between the blocks incompatible with each other, and forms a structure with a regular periodic structure by a heat treatment, etc. Specifically, the periodic structure may be cylindrical (columnar), lamellar (plate-like), or spheric (spherical).

In order to utilize the phase-separated structure of the block copolymer, it is essential for a self-organized nanostructure formed by microphase separation to be formed only in a specific region and oriented in a desired direction. In order to control a position and orientation of the nanostructure as described above, processes such as graphoepitaxy for controlling a phase separation pattern by a guide pattern and chemical epitaxy for controlling a phase separation pattern based on a difference in a chemical state of a substrate have been proposed (see, for example, Non-Patent Document 1).
Patent Document 1: Japanese Unexamined Patent Application, Publication No. 2008-36491
Non-Patent Document 1: Proc. SPIE 7637, Alternative Lithographic Technologies II, 76370G (1 Apr. 2010)

### SUMMARY OF THE INVENTION

For a method for forming a pattern using a phase-separated structure formed by self-organization of a block copolymer, it is necessary to prepare a block copolymer with a corresponding structural period (L0) for one pitch. Therefore, in the case of a multiple-pitch design, block copolymers need to be individually prepared for multiple pitches.

If a single composition for forming a phase-separated structure can be used for multiple pitches, the above-mentioned method for forming a pattern will be applied in a greatly wider range. Therefore, in the above-mentioned method for forming a pattern, there is a need for a resin composition for forming a phase-separated structure with a large process margin so that a pattern with multiple pitches can be formed without generating a pattern defect.

The present invention has been made in view of the above circumstances, and an object of the invention is to provide a resin composition for forming a phase-separated structure that can improve a process margin, and a method for producing a structure having a phase-separated structure using the resin composition for forming a phase-separated structure.

As a result of extensive studies to solve the above problem, the present invention has been completed based on findings that the above object can be solved if a resin composition for forming a phase-separated structure contains a predetermined block copolymer A and a predetermined block copolymer B and has a ratio (L0_{B}/L0_{A}) of L0 of the block copolymer B(L0_{B}) to L0 of the block copolymer A (L0_{A}) of 0.70 or more and 1.20 or less. Specifically, the present invention provides the following aspects.

A first aspect of the present invention relates to a resin composition for forming a phase-separated structure, the composition including:
a block copolymer A; and
a block copolymer B,
the block copolymer A being a block copolymer in which a first block a, a second block a, and a third block a are bonded together,
the block copolymer B being a block copolymer in which a first block b and a second block b are bonded together,
a constituent unit of a polymer constituting the first block a, a constituent unit of a polymer constituting the third block a, and a constituent unit of a polymer constituting the first block b having an identical structure to each other,
a constituent unit of a polymer constituting the second block a and a constituent unit of a polymer constituting the second block b having an identical structure to each other, and
a ratio (L0_{B}/L0_{A}) of L0 of the block copolymer B(L0_{B}) to L0 of the block copolymer A (L0_{A}) being 0.70 or more and 1.20 or less.

A second aspect of the present invention relates to the resin composition for forming a phase-separated structure as described in the first aspect, in which a ratio (A: B) of a mass of the block copolymer A to a mass of the block copolymer B ranges between 99:1 and 50:50 inclusive.

A third aspect of the present invention relates to the resin composition for forming a phase-separated structure as described in the first or second aspect, in which the first block a, the third block a, and the first block b are made of a polymer having a constituent unit including an aromatic group, and
the second block a and the second block b are made of a polymer having a constituent unit derived from an (α-substituted) acrylic ester.

A fourth aspect of the present invention relates to a method for producing a structure having a phase-separated structure, the method including:
forming a layer made of a neutralized film on a support;
applying the resin composition for forming a phase-separated structure as described in any one of the first to third aspects on the layer made of a neutralized film to form a layer including the block copolymer A and the block copolymer B; and
phase-separating the layer including the block copolymer A and the block copolymer B.

According to the present invention, a resin composition for forming a phase-separated structure that can improve a process margin, and a method for producing a structure having a phase-separated structure using the resin composition for forming a phase-separated structure can be provided.

### BRIEF DESCRIPTION OF THE DRAWINGS

FIG. 1 shows a schematic process drawing illustrating one exemplary embodiment of a method for producing a structure having a phase-separated structure; and

FIG. 2 shows a diagram illustrating one exemplary embodiment of an optional step.

### DETAILED DESCRIPTION OF THE INVENTION

Although embodiments of the present invention will be described in detail, the present invention is not limited to the embodiments below in any way and can be implemented with modifications as appropriate within the scope of the object of the present invention.

As used herein, the term “aliphatic” is defined as a relative concept to aromatic, and means, for example, a group or compound having no aromaticity.

Unless otherwise specified, the phrase “alkyl group” means a linear- or branched-chain monovalent saturated hydrocarbon group. The same applies to an alkyl group in an alkoxy group.

Unless otherwise specified, the phrase “cycloalkyl group” means a monocyclic cyclic saturated hydrocarbon group.

Unless otherwise specified, the phrase “alkylene group” means a linear- or branched-chain divalent saturated hydrocarbon group.

The phrase “halogenated alkyl group” means a group in which a portion or all of hydrogen atoms in an alkyl group is substituted with a halogen atom. Examples of the halogen atom include a fluorine atom, a chlorine atom, a bromine atom, or an iodine atom.

The phrase “fluorinated alkyl group” or “fluorinated alkylene group” means a group in which a portion or all of hydrogen atoms in an alkyl group or an alkylene group is substituted with a fluorine atom.

The phrase “constituent unit” means a monomer unit (monomeric unit) constituting a polymer compound (resin, polymer, or copolymer).

The phrase “constituent unit derived from” means a constituent unit derived from cleavage of an ethylenic double bond or a cyclic ether.

The phrase “may have a substituent” includes both a case where a hydrogen atom (—H) is substituted with a monovalent group and a case where a methylene group (—CH₂—) is substituted with a divalent group.

The term “exposure” means general irradiation with radiation.

The term “position a (carbon atom at a position a)” means a carbon atom to which a side chain of a block copolymer is bonded, unless otherwise specified. The “carbon atom at a position a” of a methyl methacrylate unit means a carbon atom to which a carbonyl group in methacrylic acid is bonded. The “carbon atom at a position a” of a styrene unit means a carbon atom to which a benzene ring is bonded.

The phrase “number average molecular weight” (Mn) means a number average molecular weight in terms of standard polystyrene as measured by size-exclusion chromatography, unless otherwise specified.

The phrase “weight average molecular weight” (Mw) means a weight average molecular weight in terms of standard polystyrene as measured by size-exclusion chromatography, unless otherwise specified. When a value of Mn or Mw is described preceding a unit (gmol-1), the value represents a molar mass.

Herein, there may be an asymmetric carbon depending on a structure represented by a chemical formula, and thus an enantiomer or a diastereomer may exist. In that case, these isomers are represented by one representative formula. These isomers may be used alone or used as a mixture.

As used herein, the phrase “structural period” means a period of a phase structure observed when a structure having a phase-separated structure is formed and refers to a sum of lengths of phases incompatible with each other. In a case where a phase-separated structure forms a cylindrical structure perpendicular to a surface of a substrate, a structural period (L0) is a distance between centers (pitch) of two adjacent cylindrical structures.

It has been known that a structural period (L0) is determined by inherent polymerization properties such as a degree of polymerization N and the Flory-Huggins interaction parameter x. That is, the larger the product “x·N” of x and N, the greater the mutual repulsion between the different blocks in the block copolymer becomes. Therefore, in the case of x·N>10.5 (hereinafter, referred to as “intensity separation limit”), repulsion between different kinds of blocks in a block copolymer is large, leading to a stronger tendency to cause phase separation. Accordingly, at the intensity separation limit, a structural period is approximately N^{2/3}*x^{1/6} and a relationship of the following expression (cy) is satisfied. That is, a structural period is proportional to the degree of polymerization N, which correlates with a molecular weight and a molecular weight ratio between different blocks.

L0∝a·N^{2/3}·x^{1/6} . . .(cy)
in which L0 denotes a structural period;
a is a parameter indicating a size of a monomer;
N denotes a degree of polymerization; and
x is an interaction parameter, and a higher value means higher phase separation performance.

Accordingly, a structural period (L0) can be controlled by adjusting a composition and a total molecular weight of a block copolymer.

### Resin Composition for Forming Phase-Separated Structure

A resin composition for forming a phase-separated structure contains a block copolymer A and a block copolymer B. The block copolymer A is a block copolymer in which a first block a, a second block a, and a third block a are bonded together, and the block copolymer B is a block copolymer in which a first block b and a second block b are bonded together. A constituent unit of a polymer constituting the first block a, a constituent unit of a polymer constituting the third block a, and a constituent unit of a polymer constituting the first block b have an identical structure to each other, and a constituent unit of a polymer constituting the second block a and a constituent unit of a polymer constituting the second block b have an identical structure to each other. A ratio (L0_{B}/L0_{A}) of L0 of the block copolymer B(L0_{B}) to L0 of the block copolymer A (L0_{A}) is 0.70 or more and 1.20 or less.

Such a resin composition for forming a phase-separated structure can be used to improve a process margin.

The reason for such an effect is unknown, but is speculated as follows.

A triblock copolymer (ABA) in which a block A, a block B, and a block A are bonded together has two attachment points that connect different kinds of block chains. Therefore, an ABA molecule takes a bridge-type molecular configuration in which two attachment points are located on different interfaces and a loop-type molecular configuration in which two attachment points are located on the same interface in a microdomain. When the ABA and a diblock copolymer (AB) have the same L0 as each other, one molecule of the ABA has a length corresponding to two molecules of the AB, so a number average molecular weight (Mn) of the ABA is twice that of the AB. Thus, a margin on a guide pitch side greater than L0 is increased in the ABA. However, when the Mn is larger, thermal mobility during annealing is reduced, phase separation does not sufficiently progress in a limited process time, and a defect tends to increase.

In contrast, when an AB with a predetermined L0 ratio to the ABA is added in addition to the ABA, thermal mobility is kept, making it easier to suppress a defect even in a limited process time and improve a process margin.

### Block Copolymer A

A block copolymer A is a block copolymer in which a first block a, a second block a, and a third block a are bonded together. A constituent unit of a polymer constituting the first block a and a constituent unit of a polymer constituting the third block a have an identical structure to each other.

The block copolymer A is preferably a block copolymer in which the first block a, the second block a, and the third block a are bonded in this order. The block copolymer A is preferably a triblock copolymer having no block other than the first block a, the second block a, and the third block a.

Examples of a polymer constituting the first block a and the third block a include a polymer having a constituent unit including an aromatic group, a polymer having a constituent unit derived from alkylene oxide, a polymer having a polyhedral oligomeric silsesquioxane structure-containing constituent unit, or the like. Among them, a polymer having a constituent unit including an aromatic group is preferred.

Examples of a polymer constituting the second block a include a polymer having a constituent unit derived from an (α-substituted) acrylic acid, a polymer having a constituent unit derived from an (α-substituted) acrylic ester, a polymer having a constituent unit of siloxane or a derivative thereof, or the like. Among them, a polymer having a constituent unit derived from an (α-substituted) acrylic ester is preferred.

Examples of the block copolymer A include a block copolymer in which a plurality of blocks having a constituent unit including an aromatic group and a block having a constituent unit derived from an (α-substituted) acrylic ester are bonded together; a block copolymer in which a plurality of blocks having a constituent unit including an aromatic group and a block having a constituent unit derived from an (α-substituted) acrylic acid are bonded together; a block copolymer bonded with a plurality of blocks having a constituent unit including an aromatic group and a block having a constituent unit of siloxane or a derivative thereof are bonded together; a block copolymer in which a plurality of blocks having a constituent unit derived from alkylene oxide and a block having a constituent unit derived from an (α-substituted) acrylic ester are bonded together; a block copolymer in which a plurality of blocks having a constituent unit derived from alkylene oxide and a block having a constituent unit derived from an (α-substituted) acrylic acid are bonded together; a block copolymer in which a plurality of blocks having a polyhedral oligomeric silsesquioxane structure-containing constituent unit and a block having a constituent unit derived from an (α-substituted) acrylic ester are bonded together; a block copolymer in which a plurality of blocks having a polyhedral oligomeric silsesquioxane structure-containing constituent unit and a block having a constituent unit derived from an (α-substituted) acrylic acid are bonded together; a block copolymer in which a plurality of blocks having a polyhedral oligomeric silsesquioxane structure-containing constituent unit and a block having constituent unit of siloxane or a derivative thereof are bonded together, or the like.

### Constituent Unit Including Aromatic Group

An aromatic group in a constituent unit including an aromatic group is a group having at least one aromatic ring.

The aromatic ring is not particularly limited as long as it is a cyclic conjugated system with 4n+2 pi-electrons, and may be an aromatic hydrocarbon ring or an aromatic heterocyclic ring. Among them, an aromatic hydrocarbon ring is preferred.

Specific examples of the aromatic group in the constituent unit including an aromatic group include a phenyl group, a naphthyl group, an anthracenyl group, a biphenylyl group, or a pyridinyl group.

The constituent unit including an aromatic group is preferably a constituent unit derived from styrene, a styrene derivative, 1-vinylnaphthalene, 4-vinylbiphenyl, 9-vinylanthracene, or vinyl pyridine, and more preferably a constituent unit derived from styrene or a styrene derivative.

The “styrene derivative” encompasses a compound in which a hydrogen atom bonded to a position a of styrene is substituted with a substituent such as an alkyl group having 1 or more and 10 or less carbon atoms, and a compound in which a hydrogen atom on a phenyl group of styrene is substituted with a substituent such as an alkyl group having 1 or more and 10 or less carbon atoms, an alkoxy group having 1 or more and 10 or less carbon atoms, a hydroxy group, a nitro group, a halogen atom, or an acetoxy group. Specific examples of the styrene derivative include α-methylstyrene, 2-methylstyrene, 3-methylstyrene, 4-methylstyrene, 4-tert-butylstyrene, 4-n-octylstyrene, 2,4,6-trimethylstyrene, 4-methoxystyrene, 4-tert-butoxystyrene, 4-hydroxystyrene, 4-nitrostyrene, 3-nitrostyrene, 4-chlorostyrene, 4-fluorostyrene, 4-acetoxystyrene, 4-chloromethylstyrene, or the like.

The constituent unit including an aromatic group also includes a constituent unit represented by Formula (u1) below.

Constituent Unit Derived from (α-Substituted) Acrylic Ester

As used herein, the “(α-substituted) acrylic ester” includes an acrylic ester and an acrylic acid derivative in which a hydrogen atom bonded to a carbon atom at a position a in an acrylic ester is substituted with a substituent.

Examples of the substituent in the (α-substituted) acrylic ester include an alkyl group having 1 or more and 5 or less carbon atoms, a halogenated alkyl group having 1 or more and 5 or less carbon atoms, or the like. Among them, an alkyl group having 1 or more and 5 or less carbon atoms is preferred and a methyl group is more preferred.

The (α-substituted) acrylic ester is preferably an (α-substituted) acrylic alkyl ester. An alkyl group in the (α-substituted) acrylic alkyl ester has preferably 1 or more and 10 or less carbon atoms and more preferably 1 or more and 5 or less carbon atoms.

Specific examples of the (α-substituted) acrylic ester include an acrylic ester such as methyl acrylate, ethyl acrylate, propyl acrylate, n-butyl acrylate, tert-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, propyltrimethoxysilane acrylate; methacrylic ester such as methyl methacrylate, ethyl methacrylate, propyl methacrylate, n-butyl methacrylate, tert-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, or propyl trimethoxysilane methacrylate; or the like.

Among them, the (α-substituted) acrylic ester is preferably acrylic alkyl ester or methacrylic alkyl ester, more preferably methyl acrylate, ethyl acrylate, tert-butyl acrylate, methyl methacrylate, ethyl methacrylate, or tert-butyl methacrylate is more preferred, and further preferably methyl methacrylate.

The constituent unit derived from an (α-substituted) acrylic ester also includes a constituent unit represented by Formula (u2) below.

Constituent Unit Derived from (α-Substituted) Acrylic Acid

As used herein, the “(α-substituted) acrylic acid” includes an acrylic acid and an acrylic acid derivative in which a hydrogen atom bonded to a carbon atom at a position a in an acrylic acid is substituted with a substituent.

Specific examples of the (α-substituted) acrylic acid include acrylic acid or methacrylic acid.

### Constituent Unit of Siloxane or Derivative Thereof

Specific examples of siloxane or a derivative thereof include dimethylpolysiloxane, diethylpolysiloxane, diphenylpolysiloxane, methylphenylpolysiloxane, or the like.

Constituent Unit Derived from Alkylene Oxide

Specific examples of alkylene oxide include ethylene oxide, propylene oxide, isopropylene oxide, butylene oxide, or the like.

### Polyhedral Oligomeric Silsesquioxane Structure-Containing Constituent Unit

Polyhedral oligomeric silsesquioxane (POSS) structure-containing constituent unit includes a constituent unit represented by General Formula (a0-1) below:

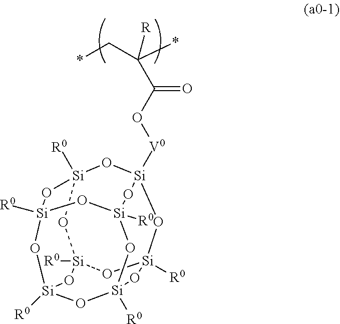

in which R denotes a hydrogen atom, an alkyl group having 1 or more and 5 or less carbon atoms, or a halogenated alkyl group having 1 or more and 5 or less carbon atoms;
V⁰ denotes a divalent organic group that may have a substituent;
R⁰ denotes a monovalent organic group that may have a substituent, and a plurality of R⁰s may be the same as or different from each other; and
* denotes a bond.

The alkyl group having 1 or more and 5 or less carbon atoms as R in Formula (a0-1) above is preferably a linear- or branched-chain alkyl group having 1 or more and 5 or less carbon atoms and specific examples thereof include a methyl group, an ethyl group, a propyl group, an isopropyl group, an n-butyl group, an isobutyl group, a tert-butyl group, a pentyl group, an isopentyl group, or a neopentyl group. The halogenated alkyl group having 1 or more and 5 or less carbon atoms is a group in which a portion or all of hydrogen atoms of the alkyl group having 1 or more and 5 or less carbon atoms is substituted with a halogen atom. Examples of the halogen atom include a fluorine atom, a chlorine atom, a bromine atom, or an iodine atom, with a fluorine atom being particularly preferred.

R is preferably a hydrogen atom, an alkyl group having 1 or more and 5 or less carbon atoms, or a fluorinated alkyl group having 1 or more and 5 or less carbon atoms, with a hydrogen atom or methyl group being most preferred from the viewpoint of industrial availability.

The monovalent organic group as R⁰ in Formula (a0-1) above has preferably 1 or more and 20 or less carbon atoms, more preferably 1 or more and 10 or less carbon atoms, and further preferably 1 or more and 8 or less carbon atoms. However, the number of carbon atoms does not include the number of carbon atoms in the below-mentioned substituent.

The monovalent organic group as R⁰ may be an aliphatic hydrocarbon group, an aromatic group, or a combination of an aliphatic hydrocarbon group and an aromatic group. Among them, an aliphatic hydrocarbon group is preferred, a monovalent aliphatic saturated hydrocarbon group is more preferred, and an alkyl group is further preferred.

Examples of the alkyl group include a linear- or branched-chain alkyl group.

The linear-chain alkyl group has preferably 1 or more and 8 or less carbon atoms, more preferably 1 or more and 5 or less carbon atoms, and further preferably 1 or more and 3 or less carbon atoms. Specific examples of the linear-chain alkyl group include a methyl group, an ethyl group, an n-propyl group, an n-butyl group, or an n-pentyl group. Among them, a methyl group, an ethyl group, or an n-propyl group is preferred, a methyl group or an ethyl group is more preferred, and an ethyl group is further preferred.

The branched-chain alkyl group has preferably 3 or more and 5 or less carbon atoms. Specific examples of the branched-chain alkyl group include an isopropyl group, an isobutyl group, a tert-butyl group, an isopentyl group, or a neopentyl group. Among them, an isopropyl group, an isobutyl group, or a tert-butyl group is preferred.

The monovalent organic group as R⁰ may be a saturated aliphatic cyclic hydrocarbon group (a group in which one hydrogen atom is removed from a saturated aliphatic cyclic hydrocarbon), a group in which the saturated aliphatic cyclic hydrocarbon group is attached to an end of the above-mentioned chain alkyl group or in which the saturated aliphatic cyclic hydrocarbon group is intervened in the above-mentioned chain alkyl group, or the like.

The saturated aliphatic cyclic hydrocarbon group may be a monocyclic group (cycloalkyl group) or a polycyclic group.

The cycloalkyl group has preferably 3 or more and 8 or less carbon atoms and more preferably 4 or more and 6 or less carbon atoms. The polycyclic group is preferably a group in which one hydrogen atom is removed from polycycloalkane having 7 or more and 12 or less carbon atoms. Specific examples of the polycycloalkane include adamantane, norbornane, isobornane, tricyclodecane, or tetracyclododecane.

The chain alkyl group may have a substituent. Examples of the substituent include a fluorine atom, a fluorinated alkyl group having 1 or more and 5 or less carbon atoms substituted with a fluorine atom, an oxygen atom (═O), or the like.

The saturated aliphatic cyclic hydrocarbon group may have a substituent. Examples of the substituent include an alkyl group having 1 or more and 5 or less carbon atoms, a fluorine atom, a fluorinated alkyl group having 1 or more and 5 or less carbon atoms, an oxygen atom (═O), or the like.

When the monovalent organic group as R⁰ may be an aromatic group-containing group, the aromatic group-containing group is a monovalent group having at least one aromatic ring.

The aromatic ring included in the aromatic group-containing group is not particularly limited as long as it is a cyclic group having a cyclic conjugated system with 4n+2 pi-electrons and may be monocyclic or polycyclic. The aromatic ring has preferably 5 or more and 30 or less carbon atoms, more preferably 5 or more and 20 or less carbon atoms, further preferably 6 or more and 15 or less carbon atoms, and particularly preferably 6 or more and 12 or less carbon atoms. However, the number of carbon atoms does not include the number of carbon atoms in the below-mentioned substituent.

Specific examples of the aromatic ring include an aromatic hydrocarbon ring such as a benzene ring, a naphthalene ring, an anthracene ring, or a phenanthrene ring; or an aromatic heterocyclic ring in which a portion of carbon atoms constituting the aromatic hydrocarbon ring is substituted with a heteroatom. Examples of the heteroatom on the aromatic hydrocarbon ring include an oxygen atom, a sulfur atom, a nitrogen atom, or the like. Specific examples of the aromatic heterocyclic ring include a pyridine ring, a thiophene ring, or the like.

Specific examples of the aromatic group include a group in which one hydrogen atom is removed from the aromatic hydrocarbon ring or the aromatic heterocyclic ring (an aryl group or a heteroaryl group); a group in which one hydrogen atom is removed from an aromatic compound including two or more aromatic rings (e.g., biphenyl or fluorene), or the like.

The aromatic group-containing group may be a group in which one of hydrogen atoms on the aromatic hydrocarbon ring or the aromatic heterocyclic ring is substituted with an alkylene group (e.g., an arylalkyl group such as a benzyl group, a phenethyl group, a 1-naphthylmethyl group, a 2-naphthylmethyl group, a 1-naphthylethyl group, or a 2-naphthylethyl group), or the like.

An alkylene group which is bonded to the aryl group or the heteroaryl group has preferably 1 or more and 4 or less carbon atoms, more preferably 1 or more and 2 or less carbon atoms, and particularly preferably one carbon atom.

The aromatic group may or may not have a substituent. Examples of the substituent include an alkyl group having 1 or more and 5 or less carbon atoms, a fluorine atom, a fluorinated alkyl group having 1 or more and 5 or less carbon atoms substituted with a fluorine atom, an oxygen atom (═O), or the like.

In Formula (a0-1) above, the divalent organic group in V⁰ may be an aliphatic hydrocarbon group or an aromatic group-containing group including an aromatic ring.

The aliphatic hydrocarbon group as the divalent organic group in V⁰ may be saturated or unsaturated, and is usually preferably saturated.

More specific examples of the aliphatic hydrocarbon group include a linear- or branched-chain aliphatic hydrocarbon group, or an aliphatic hydrocarbon group containing a ring in its structure.

The linear- or branched-chain aliphatic hydrocarbon group has preferably 1 or more and 10 or less carbon atoms, more preferably 1 or more and 6 or less carbon atoms, further preferably 1 or more and 4 or less carbon atoms, and most preferably 1 or more and 3 or less carbon atoms.

The linear-chain aliphatic hydrocarbon group is preferably a linear-chain alkylene group. Specific examples of the linear-chain alkylene group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], etc.

The branched-chain aliphatic hydrocarbon group is preferably a branched-chain alkylene group. Specific examples of the branched-chain alkylene group include an alkylalkylene group, for example, an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃)CH₂—, or —C(CH₂CH₃)₂—CH₂—; an alkyltrimethylene group such as —CH(CH₃)CH₂CH₂— or —CH₂CH(CH₃)CH₂—; or an alkyltetramethylene group such as —CH(CH₃)CH₂CH₂CH₂— or —CH₂CH(CH₃)CH₂CH₂—, etc. An alkyl group in the alkylalkylene group is preferably a linear-chain alkyl group having 1 or more and 5 or less carbon atoms.

Examples of the aliphatic hydrocarbon group containing a ring in its structure include a divalent alicyclic hydrocarbon group (a group in which two hydrogen atoms are removed from an aliphatic hydrocarbon ring), a group in which an alicyclic hydrocarbon group is bonded to an end of a linear- or branched-chain aliphatic hydrocarbon group, a group in which the alicyclic hydrocarbon group is intervened in a linear- or branched-chain aliphatic hydrocarbon group, or the like. The linear- or branched-chain aliphatic hydrocarbon group may be the same as described above.

The alicyclic hydrocarbon group has preferably 3 or more and 20 or less carbon atoms and more preferably 3 or more and 12 or less carbon atoms.

The alicyclic hydrocarbon group may be a polycyclic group or a monocyclic group. A monocyclic alicyclic hydrocarbon group is preferably a group in which two hydrogen atoms are removed from monocycloalkane. The monocycloalkane is preferably monocycloalkane having 3 or more and 6 or less carbon atoms, specifically cyclopentane, cyclohexane, or the like.

A polycyclic alicyclic hydrocarbon group is preferably a group in which two hydrogen atoms are removed from polycycoalkane, and the polycycoalkane is preferably polycycoalkane having 7 or more and 12 or less carbon atoms, specifically, adamantane, norbornane, isobornane, tricyclodecane, tetracyclododecane, or the like.

The aromatic group-containing group as V⁰ is a divalent group having an aromatic ring.

The aromatic ring is not particularly limited as long as it is a cyclic group having a cyclic conjugated system with 4n+2 pi-electrons and may be monocyclic or polycyclic. The aromatic ring has preferably 5 or more and 30 or less carbon atoms, more preferably 5 or more and 20 or less carbon atoms, further preferably 6 or more and 15 or less carbon atoms, and particularly preferably 6 or more and 12 or less carbon atoms. However, the number of carbon atoms does not include the number of carbon atoms in the below-mentioned substituent.

Specific examples of the aromatic ring include an aromatic hydrocarbon ring such as a benzene ring, a naphthalene ring, an anthracene ring, or a phenanthrene ring; an aromatic heterocyclic ring in which a portion of carbon atoms constituting the aromatic hydrocarbon ring is substituted with a heteroatom, or the like. Examples of the heteroatom on the aromatic hydrocarbon ring include an oxygen atom, a sulfur atom, a nitrogen atom, or the like. Specific examples of the aromatic heterocyclic ring include a pyridine ring, a thiophene ring, or the like.

Specific examples of the aromatic group-containing group include a group in which two hydrogen atoms are removed from the aromatic hydrocarbon ring or the aromatic heterocyclic ring (an arylene group or a heteroarylene group); or a group in which two hydrogen atoms are removed from an aromatic compound including two or more aromatic rings (e.g., biphenyl or fluorene).

The aromatic group-containing group as V⁰ may be a group in which one hydrogen atom on a group in which one hydrogen atom is removed from the aromatic hydrocarbon ring or the aromatic heterocyclic ring (an aryl group or a heteroaryl group) is substituted with an alkylene group (e.g., a group in which one hydrogen atom is further removed from an aryl group in an arylalkyl group such as a benzyl group, a phenethyl group, a 1-naphthylmethyl group, a 2-naphthylmethyl group, a 1-naphthylethyl group, or a 2-naphthylethyl group), etc.

An alkylene group which is bonded to the aryl group or the heteroaryl group has preferably 1 or more and 4 or less carbon atoms, more preferably 1 or more and 2 or less carbon atoms, and particularly preferably one carbon atom.

Specific examples of the constituent unit represented by Formula (a0-1) will be described. In Formula below, R^{a} denotes a hydrogen atom, a methyl group, or a trifluoromethyl group.

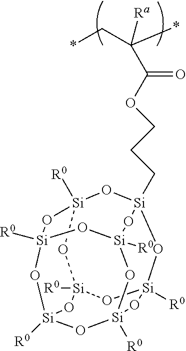

### R⁰=Ethyl Group or Isobutyl Group

More specific examples of the block copolymer A include a block copolymer in which a plurality of blocks having a constituent unit derived from styrene and a block having a constituent unit derived from methyl acrylate are bonded together; a block copolymer in which a plurality of blocks having a constituent unit derived from styrene and a block having a constituent unit derived from ethyl acrylate are bonded together; a block copolymer in which a plurality of blocks having a constituent unit derived from styrene and a block having a constituent unit derived from tert-butyl acrylate are bonded together; a block copolymer in which a plurality of blocks having a constituent unit derived from styrene and a block having a constituent unit derived from methyl methacrylate are bonded together; a block copolymer in which a plurality of blocks having a constituent unit derived from styrene and a block having a constituent unit derived from ethyl methacrylate are bonded together; a block copolymer in which a plurality of blocks having a constituent unit derived from styrene and a block having a constituent unit derived from tert-butyl methacrylate are bonded together; or a block copolymer in which a plurality of blocks having a polyhedral oligomeric silsesquioxane (POSS) structure-containing constituent unit and a block having a constituent unit derived from methyl acrylate are bonded together.

Among them, for the block copolymer A, it is preferred that each of a first block a and a third block a be made of a polymer having a constituent unit including an aromatic group, and a second block a be made of a polymer having a constituent unit derived from an (α-substituted) acrylic ester.

That is, a block copolymer in which a plurality of blocks having a constituent unit derived from styrene and a block having a constituent unit derived from methyl acrylate are bonded together; a block copolymer in which a plurality of blocks having a constituent unit derived from styrene and a block having a constituent unit derived from ethyl acrylate are bonded together; a block copolymer in which a plurality of blocks having a constituent unit derived from styrene and a block having a constituent unit derived from tert-butyl acrylate are bonded together; a block copolymer in which a plurality of blocks having a constituent unit derived from styrene and a block having a constituent unit derived from methyl methacrylate are bonded together; a block copolymer in which a plurality of blocks having a constituent unit derived from styrene and a block having a constituent unit derived from ethyl methacrylate bonded together; or a block copolymer in which a plurality of blocks having a constituent unit derived from styrene and a block having a constituent unit derived from tert-butyl methacrylate are bonded together is preferred and a block copolymer in which a plurality of blocks having a constituent unit derived from styrene and a block having a constituent unit derived from methyl methacrylate are bonded together is more preferred.

The block copolymer A is preferably a block copolymer in which each of a first block a and a third block a is made of a polymer having a constituent unit represented by General Formula (u1) below and a second block a is made of a polymer having a constituent unit represented by Formula (u2) below. Moreover, the block copolymer A may be a block copolymer in which an end of a main chain on a second block a side has an end structure represented by General Formula (e1) below.

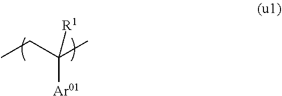

in which R¹ denotes a hydrogen atom, an alkyl group having 1 or more and 5 or less carbon atoms, or an halogenated alkyl group having 1 or more and 5 or less carbon atoms; and
Ar⁰¹ denotes an aromatic group.

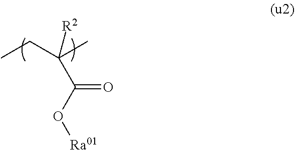

in which R² denotes a hydrogen atom, an alkyl group having 1 or more and 5 or less carbon atoms, or an halogenated alkyl group having 1 or more and 5 or less carbon atoms; and
Ra⁰¹ is an alkyl group having 1 or more and 10 or less carbon atoms.

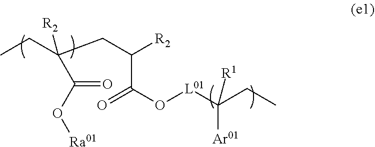

in which R¹ and R² each independently denote a hydrogen atom, an alkyl group having 1 or more and 5 or less carbon atoms, or a halogenated alkyl group having 1 or more and 5 or less carbon atoms;
Ra⁰¹ is an alkyl group having 1 or more and 10 or less carbon atoms;
Ar⁰¹ denotes an aromatic group; and
L⁰¹ denotes a divalent linking group.

### Constituent Unit Represented by General Formula (u1)

In General Formula (u1) above, R¹ denotes a hydrogen atom, an alkyl group having 1 or more and 5 or less carbon atoms, or a halogenated alkyl group having 1 or more and 5 or less carbon atoms, with a hydrogen atom being preferred.

In General Formula (u1) above, Ar⁰¹ denotes an aromatic group and may be the same as the aromatic group described in the above section [Constituent unit including aromatic group].

Among them, Ar⁰¹ is preferably a phenyl group.

### Constituent Unit Represented by General Formula (u2)

In General Formula (u2) above, R² denotes a hydrogen atom, an alkyl group having 1 or more and 5 or less carbon atoms, or a halogenated alkyl group having 1 or more and 5 or less carbon atoms, with an alkyl group having 1 or more and 5 or less carbon atoms being preferred and a methyl group being more preferred.

In General Formula (u2) above, Ra⁰¹ denotes an alkyl group having 1 or more and 10 or less carbon atoms, preferably a linear- or branched-chain alkyl group having 1 or more and 5 or less carbon atoms, more preferably a methyl group, an ethyl group, a propyl group, an isopropyl group, an n-butyl group, an isobutyl group, a tert-butyl group, a pentyl group, an isopentyl group, or a neopentyl group, and further preferably a methyl group.

End structure represented by General Formula (e1)

In General Formula (e1) above, R¹ and R² are the same as R¹ in General Formula (u1) and R² in General Formula (u2), respectively.

In General Formula (e1) above, Ra⁰¹ is the same as Ra⁰¹ in General Formula (u2) above.

In General Formula (e1) above, Ar⁰¹ is the same as Ar⁰¹ in General Formula (u1) above.

In General Formula (e1) above, L01 is a divalent linking group and preferably an alkylene group having 1 or more and 10 or less carbon atoms.

Specific examples of the alkylene group having 1 or more and 10 or less carbon atoms include a linear-chain alkylene group such as a methylene group [—CH₂—], an ethylene group [—(CH₂)₂—], a trimethylene group [—(CH₂)₃—], a tetramethylene group [—(CH₂)₄—], or a pentamethylene group [—(CH₂)₅—]; a branched-chain alkylene group such as an alkylalkylene group, for example, an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, —C(CH₂CH₃)₂—, an alkylethylene group such as —CH(CH₃)CH₂—, —CH(CH₃)CH(CH₃)—, —C(CH₃)₂CH₂—, —CH(CH₂CH₃)CH₂—, or —C(CH₂CH₃)₂—CH₂—, an alkyltrimethylene group such as —CH(CH₃)CH₂CH₂— or —CH₂CH(CH₃)CH₂—, or an alkyltetramethylene group such as —CH(CH₃)CH₂CH₂CH₂— or —CH₂CH(CH₃)CH₂CH₂—.

In General Formula (e1) above, among them, L01 is preferably a linear-chain alkylene group having 1 or more and 10 or less carbon atoms, more preferably a linear-chain alkylene group having 1 or more and 5 or less carbon atoms, and further preferably a linear-chain alkylene group having 2 or more and 5 or less carbon atoms.

In the block copolymer A, a ratio (Mn3/Mn1) of a number average molecular weight (Mn1) of a polymer constituting a first block a to a number average molecular weight (Mn3) of a polymer constituting a third block a preferably ranges between 0.05 and 1 inclusive. The ratio more preferably ranges between 0.8 and 1 inclusive, and further preferably between 0.9 and 1 inclusive from the viewpoint of ease of achievement of a good process margin. The ratio may range, for example, between 0.05 and 0.35 inclusive or 0.07 and 0.35 inclusive from the viewpoint of maintenance of thermal mobility or suppression of a defect.

The term “defect” refers to a general defect of a pattern detected when observed from right above the pattern. Examples of the defect include a defect caused by deposition of a foreign substance or a precipitate on a surface of a pattern, a defect with regard to a pattern shape such as a bridge between patterns or hole filling of a pattern, or a dislocation defect unique to a directed self-assembly (DSA) lithography.

Specifically, Mn1 is preferably 10000 or more and 100000 or less, more preferably 15000 or more and 50000 or less, and further preferably 18000 or more and 40000 or less.

Mn1 falling within the above preferred range is more likely to improve a process margin and suppress defect generation.

Specifically, Mn3 is preferably 1200 or more and 100000 or less. Mn3 is more preferably 10000 or more and 50000 or less and further preferably 18000 or more and 40000 or less from the viewpoint of ease of achievement of a good process margin. Mn3 may be, for example, 1500 or more and 11000 or less or 1800 or more and 10500 or less from the viewpoint of maintenance of thermal mobility and suppression of a defect.

Mn1 of a block copolymer A, a number average molecular weight (Mn2) of a polymer constituting the second block a, or Mn3 can be calculated, for example, as follows.

For example, when a block copolymer A is a triblock copolymer (PS-b-PMMA-b-PS′) including a first block a (PS) made of polystyrene, a second block a (PMMA) made of polymethyl methacrylate, and a third block a (PS′) made of polystyrene, the first block a and the third block a having different molecular weights, and the PS' being bonded to a side chain of the PMMA, the block copolymer A may be separated into PS-b-PMMA and PS' by hydrolysis. Mn3 can be calculated by size exclusion chromatography for the polymer PS' constituting the third block a. Furthermore, a number average molecular weight (Mn12) of a block copolymer having the first block a and the second block a can also be calculated. For the block copolymer having the first block a and the second block a, Mn1 and Mn2 can be calculated from the above-mentioned Mn12 since 1H-NMR can be used to calculate a ratio of a polymer constituting the first block a to a polymer constituting the second block a in the block copolymer.

When a number average molecular weight (Mn) of the block copolymer A and a constituent unit of a polymer constituting each block are known by 1H-NMR, Mn1, Mn2, and Mn3 can also be calculated from a L0 relationship.

The number average molecular weight (Mn) of the block copolymer A is preferably 20000 or more and 200000 or less, more preferably 30000 or more and 150000 or less, and further preferably 40000 or more and 100000 or less.

The number average molecular weight (Mn) of the block copolymer A falling within the above preferred range is more likely to improve a process margin and suppress defect generation.

A degree of dispersion (Mw/Mn) of the block copolymer A is preferably 1.0 or more and 3.0 or less, more preferably 1.0 or more and 1.5 or less, and further preferably 1.0 or more and 1.3 or less.

In the block copolymer A, a ratio of a total mass of the first block a and the third block a to a mass of the second block a (first block a and third block a: second block a) ranges preferably between 25:75 and 75:25 inclusive, more preferably between 30:70 and 70:30 inclusive, and further preferably between 40:60 and 60:40.

When the above-mentioned ratio falls within the above preferred range, a lamellar phase-separated structure oriented in a direction perpendicular to a surface of a support is more likely to be formed by a resin composition for forming a phase-separated structure according to the present embodiment. In addition, a process margin upon formation of the structure can be further improved and a defect can be further prevented from generating.

Herein, the above-mentioned ratio is calculated by ¹H-NMR.

L0 of the block copolymer A is not particularly limited, but is, for example, 10 nm or more and 60 nm or less or 10 nm or more and 40 nm or less.

Herein, L0 of a block copolymer is obtained by an evaluation method described in Example below.

### Method for Producing Block Copolymer A

A block copolymer A can be produced by any known method.

For example, the block copolymer A can be obtained by living polymerization of a monomer from which a constituent unit of a polymer constituting a first block a is derived, a monomer from which a constituent unit of a polymer constituting a second block a is derived, and a monomer from which a constituent unit of a polymer constituting a third block a is derived.

On the other hand, for example, when styrene and methyl methacrylate are used as monomers, the block copolymer A may be produced by a method including the following steps (Step A and Step B).
Step A: a step of polymerizing styrene and methyl methacrylate to obtain a block copolymer (PS-b-PMMA); and
Step B: a step of ester exchange reaction of the block copolymer (PS-b-PMMA) obtained in Step A with polystyrene having a hydroxy group at an end of a main chain.

### Step A:

Styrene and methyl methacrylate are preferably subjected to living polymerization from the viewpoint of ease of production of a block copolymer (PS-b-PMMA). Preferred examples of living polymerization include living anionic polymerization or living radical polymerization, with living anionic polymerization being particularly preferred from the viewpoint of narrower dispersion.

### Step B:

The polystyrene having a hydroxy group at an end of a main chain in Step B may be, for example, a compound represented by Formula (PS—OH) below.

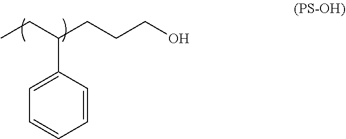

Step B may be performed in the presence of a basic catalyst. Specific examples of the basic catalyst include 1,5,7-triazabicyclo[4.4.0] deca-5-ene (TBD), etc.

A reaction temperature in Step B is preferably 50° C. or higher and 200° C. or lower and more preferably 80° C. or higher and 180° C. or lower.

A reaction time in Step B is preferably 10 hours or more and 300 hours or less.

### Block Copolymer B

A block copolymer B is a block copolymer in which a first block b and a second block b are bonded together. A constituent unit of a polymer constituting the first block b has an identical structure to a constituent unit of a polymer constituting a first block a of a block copolymer A and a constituent unit of a polymer constituting the second block b has an identical structure to a constituent unit of a polymer constituting a second block a of a block copolymer A.

The block copolymer B is preferably a diblock copolymer that has no block other than the first block b and the second block b.

A number average molecular weight (Mn) of the block copolymer B is preferably 10000 or more and 200000 or less, more preferably 20000 or more and 100000 or less, and further preferably 30000 or more and 80000 or less from the viewpoint of ease of achievement of a good process margin and suppression of defect generation.

In the block copolymer B, a ratio of a mass of the first block b to a mass of the second block b (first block b: second block b) ranges preferably between 25:75 and 75:25 inclusive, more preferably between 30:70 and 70:30 inclusive, and further preferably between 40:60 and 60:40 inclusive. When the above-mentioned ratio falls within the above preferred range, a lamellar phase-separated structure oriented in a direction perpendicular to a surface of a support is likely to be formed by a resin composition for forming a phase-separated structure according to the present embodiment. In addition, a process margin upon formation of the structure can be more improved and a defect can be further prevented from generating. Herein, the above-mentioned ratio is calculated by 1H-NMR.

L0 of the block copolymer B is not particularly limited, but is, for example, 10 nm or more and 60 nm or less or 10 nm or more and 40 nm or less.

A ratio (L0_{B}/L0_{A}) of L0 of the block copolymer B(L0_{B}) to L0 of the block copolymer A (L0_{A}) is 0.70 or more and 1.20 or less, preferably 0.80 or more and 1.10 or less, and more preferably 0.90 or more and 1.00 or less from the viewpoint of ease of achievement of a good process margin.

A ratio (A: B) of a mass of the block copolymer A to a mass of the block copolymer B ranges preferably between 99:1 and 50:50 inclusive, more preferably between 90:10 and 60:40 inclusive, and further preferably between 80:20 and 70:30 inclusive from the viewpoint of ease of achievement of a good process margin.

### Organic Solvent Component

A resin composition for forming a phase-separated structure preferably includes an organic solvent.

Any organic solvent may be used as an organic solvent component as long as it can dissolve each component to be used and form a homogeneous solution. Conventionally, any organic solvent selected from known organic solvents as a solvent for a composition including a resin as a main component may be used.

Examples of the organic solvent component include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a compound having an ester bond such as ethylene glycol monoacetate, diethylene glycol monoacetate, propylene glycol monoacetate, or dipropylene glycol monoacetate; a derivative of the polyhydric alcohol such as a compound having an ether bond such as a monoalkyl ether such as monomethyl ether, monoethyl ether, monopropyl ether, or monobutyl ether, or a monophenyl ether of the polyhydric alcohol or the compound having an ester bond [among them, propylene glycol monomethyl ether acetate (PGMEA) or propylene glycol monomethyl ether (PGME) is preferred]; a cyclic ether such as dioxane, or an ester such as methyl lactate, ethyl lactate (EL), methyl acetate, ethyl acetate, butyl acetate, methyl pyruvate, ethyl pyruvate, methyl methoxy propionate, or ethyl ethoxy propionate; an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene.

The organic solvent component may be used alone, or two or more thereof may be used as a mixed solvent. Among them, propylene glycol monomethyl ether acetate (PGMEA), propylene glycol monomethyl ether (PGME), cyclohexanone, or ethyl lactate (EL) is preferred.

A mixed solvent of PGMEA and a polar solvent is also preferred. A mass ratio (PGMEA: polar solvent) thereof may be appropriately determined taking into consideration compatibility of PGMEA and the polar solvent, etc., but the ratio ranges preferably between 1:9 and 9:1 inclusive and more preferably between 2:8 and 8:2 inclusive.

For example, when EL is blended as the polar solvent, a mass ratio of PGMEA: EL ranges preferably between 1:9 and 9:1 inclusive and more preferably between 2:8 and 8:2 inclusive. When PGME is blended as the polar solvent, a mass ratio of PGMEA: PGME ranges preferably between 1:9 and 9:1 inclusive, more preferably between 2:8 and 8:2 inclusive, and further preferably between 3:7 and 7:3 inclusive. When PGME and cyclohexanone are blended as the polar solvent, a mass ratio of PGMEA: (PGME+cyclohexanone) ranges preferably between 1:9 and 9:1 inclusive, more preferably between 2:8 and 8:2 inclusive, and further preferably between 3:7 and 7:3 inclusive.

In addition to those described above, a mixed solvent of PGMEA, EL, or the mixed solvent of PGMEA and a polar solvent with γ-butyrolactone is also preferred as the organic solvent component in the resin composition for forming a phase-separated structure. In this case, they are preferably mixed in a mass ratio of the former to the latter ranging between 70:30 and 95:5 inclusive.

A concentration of the organic solvent component included in the resin composition for forming a phase-separated structure is not particularly limited as long as it may be applied, and is appropriately set depending on a thickness of a coated film. The organic solvent component is generally used so as to give a solid content concentration in a range of 0.2% to 70% by mass and preferably 0.2% to 50% by mass.

### Optional Component

A resin composition for forming a phase-separated structure may contain an optional component other than the block copolymer A, the block copolymer B, and the organic solvent component as mentioned above.

Examples of the optional component include another resin, a surfactant, a dissolution inhibiting agent, a plasticizing agent, a stabilizing agent, a coloring agent, an anti-halation agent, a dye, a sensitizing agent, a base proliferating agent, or a basic compound.

### Method for Producing Structure Including Phase-Separated Structure

A method for producing a structure having a phase-separated structure includes a step of forming a layer made of a neutralized film on a support (hereinafter referred to as “Step (i)”); a step of applying the above-mentioned resin composition for forming a phase-separated structure on the layer made of a neutralized film to form a layer including a block copolymer A and a block copolymer B (hereinafter referred to as “Step (ii)”); and a step of phase-separating the layer including a block copolymer A and a block copolymer B (hereinafter referred to as “Step (iii)”).

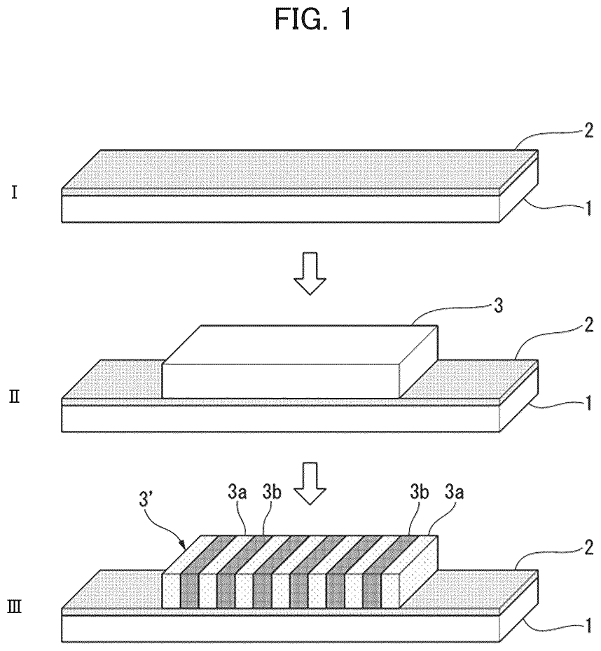

Such a method for producing a structure having a phase-separated structure will be specifically described with reference to FIG. 1. However, the present invention is not limited thereto.

FIG. 1 shows one exemplary embodiment of a method for producing a structure having a phase-separated structure.

In the embodiment shown in FIG. 1, an undercoat agent is first applied on a support 1 to form a layer made of a neutralized film 2 (FIG. 1 (I); Step (i)).

Next, the above-mentioned resin composition for forming a phase-separated structure is applied on the layer made of a neutralized film 2 to form a layer including a block copolymer A and a block copolymer B(BCP layer) 3 (FIG. 1 (II); Step (ii)).

Then, the resultant is annealed by heating to separate the BCP layer 3 into a phase 3a and a phase 3b (FIG. 1 (III); Step (iii)).

According to the method according to such an embodiment, i.e., the method including Step (i) to Step (iii), a structure having a phase-separated structure 3′ is produced on the layer made of a neutralized film 2.

### Step (i)

In Step (i), a layer made of a neutralized film 2 is formed on a support 1.

In the embodiment shown in FIG. 1, an undercoat agent is first applied on the support 1 to form the layer made of a neutralized film 2.

By providing the layer made of a neutralized film 2 on the support 1, a hydrophilic-hydrophobic balance can be achieved between a surface of the support 1 and the layer including the block copolymers (BCP layer) 3.

A kind of the support 1 is not particularly limited as long as the resin composition can be applied on its surface. Examples thereof include a substrate made of an inorganic material such as a metal (e.g., silicon, copper, chromium, iron, or aluminum), glass, titanium oxide, silica, or mica; a substrate made of an oxide such as SiO2; a substrate made of a nitride such as SiN; a substrate made of an oxynitride such as SiON; or a substrate made of an organic material such as acryl, polystyrene, cellulose, cellulose acetate, or a phenolic resin. Among them, a metal substrate is suitable, for example, a lamellar structure is likely to be formed on a silicon substrate (Si substrate) or a copper substrate (Cu substrate). Among them, a Si substrate is particularly suitable.

A size or shape of the support 1 is not particularly limited. The support 1 does not necessarily have a smooth surface, and substrates having various shapes can be appropriately selected. For example, a substrate having a curved surface, a flat plate having an uneven surface, or a flaky substrate may be used.

An inorganic and/or organic film may be provided on a surface of the support 1.

Examples of the inorganic film include an inorganic antireflection film (inorganic BARC) or the like.

Examples of the organic film include an organic antireflection film (organic BARC) or the like. The inorganic film can be formed, for example, by applying an inorganic antireflection film composition such as a silicon-based material on a support and baking the resultant. The organic film can be formed, for example, by applying a material for forming an organic film in which a resin component constituting the organic film is dissolved in an organic solvent on a substrate using a spinner, etc., and baking the resultant under heating conditions of preferably 200° C. or higher and 300° C. or lower for preferably 30 seconds or more and 300 seconds or less and more preferably for 60 seconds or more and 180 seconds or less. This material for forming an organic film does not necessarily need sensitivity to light or electron beams like a resist film, and may or may not have the sensitivity. Specifically, a resist or a resin generally used for producing a semiconductor element or a liquid crystal display element may be used.

Furthermore, the material for forming an organic film is preferably a material capable of forming an organic film that can be subjected to etching, particularly dry-etching so that a pattern may be formed on the organic film by transferring a pattern of the phase-separated structure on the organic film. Among them, a material capable of forming an organic film that can be subjected to etching such as oxygen plasma etching is preferably used. Such a material for forming an organic film may be a material conventionally used for forming an organic film such as organic BARC. Examples thereof include ARC series manufactured by Nissan Chemical Corporation, AR series manufactured by Rohm and Haas Japan Ltd., or SWK series manufactured by TOKYO OHKA KOGYO CO., LTD.

A resin composition can be used as an undercoat agent.

The resin composition for the undercoat agent can be appropriately selected from conventionally known resin compositions to be used for forming a thin film depending on a kind of a block constituting a block copolymer.

The resin composition for the undercoat agent may be, for example, a thermopolymerizable resin composition or may be a photosensitive resin composition such as a positive-type resist composition or a negative-type resist composition. Furthermore, a non-polymerizable film formed by applying a compound serving as a surface treating agent may be used as a neutralized layer. For example, a siloxane-based organic monomolecular film formed by applying phenethyltrichlorosilane, octadecyltrichlorosilane, hexamethyldisilazane, or the like as a surface-treating agent can also be suitably used as the neutralized layer.

For example, a composition containing a resin having both styrene and methyl methacrylate as a constituent unit or a compound or a composition including both a moiety having a high affinity with styrene such as an aromatic ring and a moiety having a high affinity with methyl methacrylate (e.g., a highly polar functional group) is preferably used as the resin composition for the undercoat agent.

Examples of the resin having both styrene and methyl methacrylate as a constituent unit include a random copolymer of styrene and methyl methacrylate, an alternating polymer of styrene and methyl methacrylate (polymer in which each monomer is alternately copolymerized), or the like. Furthermore, examples of the composition including both a moiety having a high affinity with styrene and a moiety having a high affinity with methyl methacrylate include a composition containing a resin obtained by polymerizing at least a monomer having an aromatic ring and a monomer having a high polarity functional group. Examples of the monomer having an aromatic ring include a monomer having an aryl group in which one hydrogen atom is removed from an aromatic hydrocarbon ring such as a phenyl group, a biphenyl group, a fluorenyl group, a naphthyl group, an anthryl group, or a phenanthryl group; or a heteroaryl group in which a portion of carbon atoms constituting a ring on any of the above-mentioned groups is substituted with a heteroatom such as an oxygen atom, a sulfur atom or a nitrogen atom. Furthermore, examples of the monomer having a highly polar functional group include a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group.

Furthermore, examples of the compound including both a moiety having a high affinity with styrene and a moiety having a high affinity with methyl methacrylate include a compound including both an aryl group and a highly polar functional group such as phenethyltrichlorosilane; or a compound including both an alkyl group and a highly polar functional group such as an alkylsilane compound.

The resin composition for the undercoat agent can be produced by dissolving the above-mentioned resin in a solvent.

Such a solvent may be any solvent as long as it can dissolve a component to be used and form a homogeneous solution. For example, the same organic solvent component as one exemplified in the above-mentioned description for the resin composition for forming a phase-separated structure may be used.

A method for forming the layer made of a neutralized film 2 by applying the undercoat agent on the support 1 is not particularly limited and may be any conventionally known method.

For example, the layer made of a neutralized film 2 can be formed by applying the undercoat agent on the support 1 using a conventionally known method such as a spin coating or use of a spinner to form a coated film, and drying the coated film.

A method for drying the coated film is not limited as long as a solvent included in the undercoat agent can be volatilized, and, for example, baking may be used. In this case, a baking temperature is preferably 80° C. or higher and 300° C. or lower, more preferably 180° C. or higher and 270° C. or lower, and further preferably 220° C. or higher and 250° C. or lower. A baking time is preferably 30 seconds or more and 500 seconds or less and more preferably 60 seconds or more and 400 seconds or less.

A thickness of the layer made of a neutralized film 2 after drying the coated film is preferably about 10 nm or more and 100 nm or less and more preferably about 40 nm or more and to 90 nm or less.

A surface of the support 1 may be previously cleaned before the layer made of a neutralized film 2 is formed on the support 1. Cleaning of the surface of the support 1 improves coatability of the undercoat agent.

A conventionally known cleaning treatment method can be used, and examples thereof include an oxygen plasma treatment, an ozone oxidation treatment, an acid alkali treatment, a chemical modification treatment, or the like.

After the layer made of a neutralized film 2 is formed, the layer made of a neutralized film 2 may be rinsed with a rinsing liquid such as a solvent, as necessary. Since an uncrosslinked portion of the layer made of a neutralized film 2 is removed by rinsing, affinity with at least one block constituting a block copolymer is improved, and thus, a phase-separated structure having a lamellar structure oriented in a direction perpendicular to a surface of the support 1 is likely to be formed.

Note that, the rinsing liquid may be any liquid as long as it can dissolve the uncrosslinked portion and, for example, propylene glycol monomethyl ether acetate (PGMEA), propylene glycol monomethyl ether (PGME), ethyl lactate (EL), or a commercially available thinner liquid may be used.

After the cleaning, post-baking may be performed in order to volatilize the rinsing liquid. A temperature condition during the post-baking is preferably 80° C. or higher and 300° C. or lower, more preferably 100° C. or higher and 270° C. or lower, and further preferably 120° C. or higher and 250° C. or lower. A baking time is preferably 30 seconds or more and 500 seconds or less and more preferably 60 seconds or more and 240 seconds or less. A thickness of the layer made of a neutralized film 2 after such post-baking is preferably about 1 nm or more and 10 nm or less and more preferably about 2 nm or more and 7 nm or less.

### Step (ii)

In Step (ii), a resin composition for forming a phase-separated structure is then applied on the layer made of a neutralized film 2 to form a layer including a block copolymer A and a block copolymer B(BCP layer) 3.

A method of forming the BCP layer 3 on the layer made of a neutralized film 2 is not particularly limited, and, for example, may be a method including applying the resin composition for forming a phase-separated structure according to the above-mentioned embodiment on the layer made of a neutralized film 2 by a conventionally known method such as spin coating or use of a spinner to form a coated film and drying the coated film.

A thickness of the BCP layer 3 may only be sufficient for phase separation to occur. Considering a kind of the support 1, or a size of a structural period or uniformity of a nanostructure of the phase-separated structure to be formed, the thickness is 20 nm or more and 100 nm or less and more preferably 30 nm or more and 80 nm or less.

For example, when the support 1 is a Si substrate, a thickness of the BCP layer 3 is preferably adjusted to 10 nm or more and 100 nm or less and more preferably 30 nm or more and 80 nm or less.

Step (iii)

In Step (iii), the BCP layer 3 formed on the layer made of a neutralized film 2 is phase-separated.

After Step (ii), the support 1 is annealed by heating to produce a structure 3′ having a phase-separated structure separated into a phase 3a and a phase 3b on the layer made of a neutralized film 2. In a subsequent step, the phase is selectively removed to expose at least a portion of the layer made of a neutralized film 2.

A temperature condition during the annealing treatment is preferably a glass transition temperature of a block copolymer used or higher and lower than its thermal decomposition temperature. For example, in the case of a polystyrene-polymethyl methacrylate (PS-PMMA) block copolymer (weight average molecular weight: 5000 or more and 100000 or less), the temperature condition is preferably 180° C. or higher and 270° C. or lower, more preferably 200° C. or higher and 270° C. or lower, and further preferably 220° C. or higher and 260° C. or lower.

A heating time is preferably 1 minute or more and 1 hour or less, more preferably 2 minutes or more and 45 minutes or less, and further preferably 5 minutes or more and 30 minutes or less.

The annealing treatment is preferably performed in a less reactive gas such as nitrogen.

The method for producing a structure having a phase-separated structure according to the above-described embodiment has a good process margin since the resin composition for forming a phase-separated structure according to the above-described embodiment is used.

In addition, the structure having a phase-separated structure according to the present embodiment can produce a support with a nanostructure that is more freely designed in terms of position and orientation on a surface of the support.

For example, according to the method for producing a structure having a phase-separated structure according to the present embodiment, a phase-separated structure having a lamellar structure is likely to be formed.

### Optional Step

A method of producing a structure having a phase-separated structure is not limited to the above-mentioned embodiment and may include a step other than Step (i) to Step (iii) (optional step).

Such an optional step includes a step of selectively removing a phase made of at least one of blocks constituting a block copolymer from a BCP layer 3 (hereinafter referred to as “Step (iv)”) and a guide pattern formation step.

### Step (iv)

In Step (iv), a phase made of at least one of blocks constituting a block copolymer is selectively removed from the BCP layer 3 which is formed on a layer made of a neutralized film 2. This results in formation of a fine pattern (polymer nanostructure).

Examples of the method for selectively removing the phase made of the block include a method for subjecting the BCP layer to an oxygen plasma treatment or a method for subjecting the BCP layer to a hydrogen plasma treatment.

For example, when the BCP layer including the block copolymer is phase-separated and then the BCP layer is subjected to an oxygen plasma treatment or a hydrogen plasma treatment, a phase made of a first block a and a third block a is not selectively removed, but a phase made of a second block a is selectively removed.

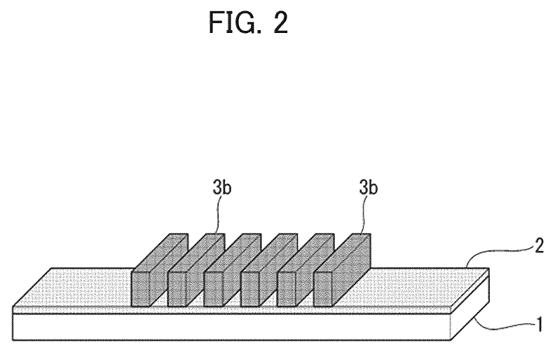

FIG. 2 shows one exemplary embodiment of Step (iv).

In the embodiment shown in FIG. 2, a structure 3′ produced on a support 1 in Step (iii) is subjected to an oxygen plasma treatment to thereby selectively remove a phase 3a, resulting in formation of a pattern (polymer nanostructure) constituted of phases 3b apart from each other.

The support 1 with a pattern formed by phase separation of the BCP layer 3 made of the block copolymer as described above can be used as is, or a shape of the pattern (polymer nanostructure) on the support 1 can be changed by further heating.

A temperature condition during the heating is preferably a glass transition temperature of the block copolymer used or higher and lower than its thermal decomposition temperature. The heating is preferably performed in a less reactive gas such as nitrogen.

### Guide Pattern Formation Step

A method for producing a structure having a phase-separated structure may include a step of forming a guide pattern on a layer made of a neutralized film 2 (guide pattern forming step). This allows an array structure of the phase-separated structure to be controlled.

For example, even a block copolymer from which a fingerprint-shaped phase-separated structure is randomly formed when a guide pattern is not provided, a groove structure of a resist film can be provided on the layer made of a neutralized film to obtain a phase-separated structure oriented along the groove. Further, in the case where a surface of a guide pattern has an affinity with any of blocks constituting the above-mentioned block copolymer, a phase-separated structure having a lamellar structure oriented in a direction perpendicular to a surface of a support 1 is likely to be formed.

A guide pattern can be formed using, for example, a resist composition.

For a resist composition for forming a guide pattern, a resist composition having an affinity with any of blocks constituting the block copolymer can be appropriately selected from a resist composition to be generally used for forming a resist pattern or a modified product thereof. The resist composition may be either a positive-type resist composition from which a positive-type pattern is formed, that is, an exposed area of a resist film is dissolved and removed or a negative-type resist composition from which a negative-type pattern is formed, that is, an unexposed area of a resist film is dissolved and removed, with the negative-type resist composition being preferred. The negative-type resist composition is preferably a resist composition that contains, for example, an acid generating agent and a base material component having a solubility in an organic solvent-containing developing solution that decreases under action of an acid, the base material component containing a resin component that has a constituent unit degraded under action of an acid to have an increased polarity.

After a resin composition for forming a phase-separated structure is poured onto a layer made of a neutralized film with a guide pattern, an annealing treatment is performed to cause phase separation. Therefore, a resist composition capable of forming a resist film having excellent solvent resistance and heat resistance is preferably used as a resist composition for forming a guide pattern.

### EXAMPLES

Although the present invention will be described in more detail with reference to Examples, the present invention is not limited to Examples.

A block copolymer A and a block copolymer B used in Examples or Comparative Examples will be described below. Note that, a number average molecular weight (Mn), a copolymer composition ratio (PS: PMMA), and L0 of the block copolymer A and the block copolymer B, as well as a ratio (Mn3/Mn1) of a number average molecular weight of a polymer constituting a third block a (Mn3) to that of a polymer constituting a first block a (Mn1) of the block copolymer A are shown in Table 1.

(Block copolymer A)

A1: a triblock copolymer (PS-b-PMMA-b-PS) having a first block a (PS) made of polystyrene, a second block a (PMMA) made of polymethyl methacrylate, and a third block a (PS) made of polystyrene, the first block a and the third block a having the same molecular weight.

A2: a triblock copolymer (PS-b-PMMA-b-PS′) having a first block a (PS) made of polystyrene, a second block a (PMMA) made of polymethyl methacrylate, and a third block a (PS′) made of polystyrene, the first block a and the third block a having different molecular weights, the copolymer being obtained by the below-mentioned synthetic example.

Block copolymer B

B1 to B4: diblock copolymers (PS-b-PMMA) having a first block b (PS) made of polystyrene and a second block b (PMMA) made of polymethyl methacrylate

Synthetic example of A2

A stirring bar, 500 mg of PS-b-PMMA, and 250 mg of a compound represented by Formula (PS—OH) below were added to a flask with a greaseless valve (30 mL). The flask was heated so as to have an internal temperature of 100° C. in an aluminum bath. A content of the flask was dried overnight under vacuum at the same temperature. After drying, 5 mg (0.0357 mmol) of TBD (1,5,7-triazabicyclo[4.4.0] deca-5-ene) dissolved in 5 mL of toluene was added to the flask. The flask was then heated at 150° C. in an aluminum bath and a content of the flask was stirred at the same temperature. After stirring and allowing an internal temperature of the flask to return to room temperature, about 5 mg of benzoic acid was added to the flask. The resulting product was then re-precipitated in MeOH at room temperature. The resulting precipitate was then dried under vacuum. A sample (300 mg portion only) was dispersed in cyclohexane, stirred at 75° C. for 15 minutes, and centrifuged. Then, the solvent was removed. This process was performed three times. After the third centrifugation, the resultant was re-precipitated and dried under vacuum to obtain A2 (PS-b-PMMA-b-PS′).

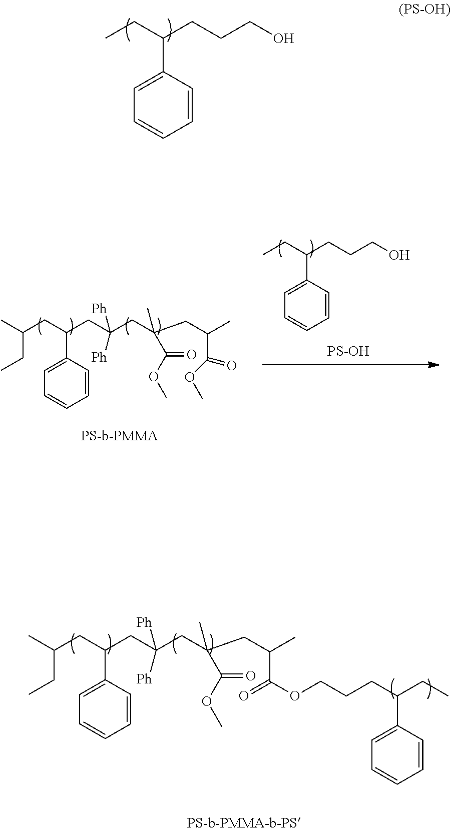

TABLE 1

| | | | PS:PMMA | L0 | |
|---|---|---|---|---|---|
| | | Mn | (wt %) | (nm) | Mn3/Mn1 |
| Block copolymer A | A1 | 88000 | 50:50 | 23.9 | 1 |
| | (PS-b-PMMA-b-PS) | | | | |
| | A2 | 58000 | 53:47 | 23.0 | 0.13 |
| | (PS-b-PMMA-b-PS′) | | | | |
| Block copolymer B | B1 | 42000 | 50:50 | 22.7 | — |
| (PS-b-PMMA) | B2 | 50000 | 50:50 | 25.7 | — |
| | B3 | 56000 | 50:50 | 27.5 | — |
| | B4 | 63000 | 50:50 | 29.7 | — |

### <Preparation of Resin Composition for Forming Phase-Separated Structure>

A resin composition for forming a phase-separated structure (solid content concentration: 1.3% by mass) was prepared by dissolving the block copolymer A and the block copolymer B having the types and proportions listed in Tables 2 and 3 in propylene glycol monomethyl ether acetate (PGMEA).

### [Evaluation of Structural Period (L0)]

A 12-inch silicon wafer was coated with a resin composition for forming a neutralized film, that is, a 2% by mass solution of a styrene/methyl methacrylate/2-hydroxyethyl methacrylate copolymer (copolymerization ratio: styrene/methyl methacrylate/2-hydroxyethyl methacrylate=82/12/6 (% by mass)) in PGMEA using a spinner. The resulting coated film was baked at 250° C. for 300 seconds to form a layer made of a neutralized film with a film thickness of 60 nm on the silicon wafer.

Next, a portion of the neutralized film other than those adhering to the silicon wafer was removed with a solvent (OK73 thinner, manufactured by TOKYO OHKA KOGYO CO., LTD.). A 1.3% by mass solution of a block copolymer A or a block copolymer B in PGMEA was spin-coated on the layer made of a neutralized film, and then soft-baked at 90° C. for 60 seconds to form a block copolymer layer with a film thickness of 35 nm.

The resulting silicon wafer was annealed by heating at 250° C. for 30 minutes under a nitrogen gas flow to form a structure having a phase-separated structure. The block was then selectively removed to form a fingerprint pattern. The thus-formed pattern was imaged using a length-measuring scanning electron microscope (CG6300 (manufactured by Hitachi High-Tech Corporation)). The resulting 100 images were analyzed using an image analysis software (DSA-APPS (manufactured by Hitachi High-Tech Corporation)), and an average value of L0 was determined based on L0 values calculated for the 100 images. The results are shown as “L0 (nm)” in Table 1.

### Evaluation of Process Margin

A 12-inch silicon wafer with a silicon nitride film serving as an antireflection film was coated with a resin composition for forming a polystyrenated film, that is, a 0.4% by mass solution of a styrene/vinylbenzocyclobutene copolymer in PGMEA using a spinner. The resulting coated film was baked at 250° C. for 300 seconds to form a layer made of a polystyrenated film with a film thickness of 8 nm on the silicon wafer.

Then, the polystyrenated film was coated with an ArF photoresist for immersion exposure to form a coated film. The resulting coated film was then baked at 90° C. for 60 seconds.

Next, the thus-baked coated film was exposed with an ArF immersion exposure device (ASML NXT1900i scanner, NA: 1.35, quadrupole, 0.87, 0.72), followed by post-exposure bake at 110° C. for 60 seconds.

After development, the polystyrenated film was patterned by plasma etching using oxygen/nitrogen plasma, resist stripping, and then post-baking at 100° C. for 60 seconds. The thus-patterned polystyrene film was coated with a resin composition for forming a neutralized film, that is, a 2% by mass solution of a styrene/methyl methacrylate/hydroxyethyl methacrylate copolymer in PGMEA to form a coated film. The thus-formed coated film was baked at 250° C. for 300 seconds, rinsed with OK73 thinner, and post-baked at 100° C. for 60 seconds to obtain a guide substrate for evaluation with a guide pattern constituted of alternately repeating polystyrenated films and neutralized films.

The resulting guide substrate was divided into small pieces for each repeating pattern and used for evaluation.

The guide substrate was coated with a resin composition for forming a phase-separated structure to form a coated film. The coated film was baked at 90° C. for 60 seconds and then annealed at 250° C. for 5 hours to form a phase-separation pattern.

Oxygen plasma ashing was then used to make a surface of the phase-separation pattern uneven. Next, the surface of the phase-separation pattern was subjected to platinum deposition. A surface of the thus-platinum-deposited phase-separation pattern was observed with a scanning electron microscope (SEM, SU8000 (manufactured by Hitachi High-Tech Corporation)). A number of defect-free cells was counted in guides with guide pitches (X-direction, width of one cycle in the guide pattern) and guide dimensions (Y-direction, width of the polystyrenated film in the guide pattern). A higher number of defect-free cells means that one block copolymer can be used for multiple pitches. The results are shown as “process margin” in Tables 2 and 3.

TABLE 2

| | Block copolymer A | Block copolymer B | A:B | | Process |
|---|---|---|---|---|---|
| | (PS-b-PMMA-b-PS) | (PS-b-PMMA) | (wt %) | L0_{B}/L0_{A} | margin |
| Example 1 | A1 | B1 | 75:25 | 0.950 | 113 |
| Example 2 | A1 | B1 | 50:50 | 0.950 | 104 |
| Example 3 | A1 | B2 | 75:25 | 1.075 | 105 |
| Example 4 | A1 | B3 | 75:25 | 1.151 | 98 |
| Comparative | A1 | — | 100:0 | — | 92 |
| Example 1 | | | | | |
| Comparative | — | B1 | 0:100 | — | 24 |
| Example 2 | | | | | |
| Comparative | A1 | B4 | 75:25 | 1.243 | 86 |
| Example 3 | | | | | |

TABLE 3

| | Block copolymer A | Block copolymer B | A:B | | Process |
|---|---|---|---|---|---|
| | (PS-b-PMMA-b-PS′) | (PS-b-PMMA) | (wt %) | L0_{B}/L0_{A} | margin |
| Example 5 | A2 | B1 | 75:25 | 0.987 | 81 |
| Example 6 | A2 | B2 | 75:25 | 1.117 | 77 |
| Example 7 | A2 | B3 | 75:25 | 1.196 | 73 |
| Comparative | A2 | — | 100:0 | — | 66 |
| Example 4 | | | | | |

As shown in Tables 1 and 2, it can be seen that the resin compositions for forming a phase-separating structure according to Examples containing the predetermined block copolymer A and the predetermined block copolymer B and having L0_{B}/L0_{A} of 0.70 or more and 1.20 or less have a better process margin than the resin compositions for forming a phase-separated structure according to Comparative Examples.

What is claimed is:

1. A resin composition for forming a phase-separated structure, the composition comprising:
a block copolymer A; and
a block copolymer B,
wherein the block copolymer A is a block copolymer in which a first block a, a second block a, and a third block a are bonded together,
the block copolymer B is a block copolymer in which a first block b and a second block b are bonded together,
a constituent unit of a polymer constituting the first block a, a constituent unit of a polymer constituting the third block a, and a constituent unit of a polymer constituting the first block b have an identical structure to each other,
a constituent unit of a polymer constituting the second block a and a constituent unit of a polymer constituting the second block b have an identical structure to each other, and
a ratio (L0_{B}/L0_{A}) of L0 of the block copolymer B(L0_{B}) to L0 of the block copolymer A (L0_{A}) is 0.70 or more and 1.20 or less.

2. The resin composition for forming a phase-separated structure according to claim 1, wherein a ratio (A: B) of a mass of the block copolymer A to a mass of the block copolymer B is between 99:1 and 50:50 inclusive.

3. The resin composition for forming a phase-separated structure according to claim 1, wherein the first block a, the third block a, and the first block b are made of a polymer comprising a constituent unit comprising an aromatic group, and
the second block a and the second block b are made of a polymer comprising a constituent unit derived from an (α-substituted) acrylic ester.

4. A method for producing a structure comprising a phase-separated structure, the method comprising:
forming a layer made of a neutralized film on a support;
applying the resin composition for forming a phase-separated structure according to claim 1 on the layer made of a neutralized film to form a layer comprising the block copolymer A and the block copolymer B; and
phase-separating the layer comprising the block copolymer A and the block copolymer B.
